(19) United States
(12) Patent Application Publication
(10) Pub. No.: US 2015/0357065 A1
(43) Pub. Date: Dec. 10, 2015

(54) BODY SHIELD FOR THERMAL AND ELECTROMAGNETIC RADIATION

(71) Applicant: Icaro Innovations Corporation, Bradenton Beach, FL (US)

(72) Inventor: Daniel T. DeBaun, Bradenton Beach, FL (US)

(73) Assignee: Icaro Innovations Corporation

(21) Appl. No.: 14/699,919

(22) Filed: Apr. 29, 2015

Related U.S. Application Data
(63) Continuation-in-part of application No. 14/275,495, filed on May 12, 2014.
Application No. 14/275,495 is a continuation-in-part of application No. 13/709,875, filed on Dec. 10, 2012.
(60) Provisional application No. 61/570,546, filed on Dec. 14, 2011.

(51) Int. Cl. G21F 1/12; H05K 9/00

(52) U.S. Cl. CPC G21F 1/125; H05K 9/0052

(57) ABSTRACT

A body shield (10) is disclosed for protecting a user from harmful thermal and electromagnetic radiation. The body shield includes a body portion (31) and a cover (32) having sidewalls (80 and 81). The body portion has a multi-layered core (11) which is surrounded by an outer casing (12). The multi-layered core includes a first layer (14) of a magnetic metal alloy for shielding extremely low frequency electromagnetic radiation, a second layer (15) of a carbon based material for absorbing higher frequency electromagnetic radiation, and a third layer (16) of a non-magnetic material for conducting higher frequency electromagnetic radiation. The core may be incorporated into a body portion coupled to the device, a cover overlaying the device, or both.

### REFERENCE TO RELATED APPLICATION

This is a continuation-in-part of U.S. patent application Ser. No. 14/275,495 filed May 12, 2014, which is a continuation-in-part of U.S. patent application Ser. No. 13/709,875 filed Dec. 10, 2012 which claims the benefit of U.S. Provisional Patent Application Ser. No. 61/570,546 filed Dec. 14, 2011.

### TECHNICAL FIELD

This invention relates to shields used to protect a person and devices from thermal and electromagnetic radiation, and particularly from harmful thermal and low to high electromagnetic radiation produced by electronic devices.

### BACKGROUND OF THE INVENTION

In today's society people are constantly coming into contact with harmful electromagnetic radiation from electronic devices such as tablet computers, laptop computers, cellular telephones, handheld tablet computers, handheld personal data devices (pda), and other electronic devices. The close proximity of these devices to the user exposes the person to an increase in excess levels of heat as well as low frequency to high frequency electromagnetic fields and radiations. This exposure to a person can cause serious medical issues.

As such, many devices are designed to include internal shields to reduce exposure to the user. These internal shields however are directional in nature and do not always provide adequate protection. Furthermore, these shields are typically designed to reduce one particular type of radiation and do not reduce a wide spectrum of radiations.

Accordingly, it is seen that a body shield that protects a user from different types of electromagnetic radiations associated with personal electronic devices is needed. It is to the provision of such therefore that the present invention is primarily directed.

### SUMMARY OF THE INVENTION

A body shield for shielding a person from thermal and electromagnetic radiation from a portable electronic device, the body shield comprises an outer covering having a core and an outer casing encasing said core, the outer covering including a central portion configured to removably overlay a top surface of the portable electronic device and at least one sidewall extending from the central portion configured to overlay a side surface of the portable electronic device. The core includes a first layer having a material composition for shielding extremely low frequency electromagnetic radiation, a second layer having a material composition for absorbing higher frequency electromagnetic radiation.

### BRIEF DESCRIPTION OF THE DRAWING

FIG. 1 is a perspective view of a body shield embodying principles of the invention in a preferred form.

FIG. 2 is an exploded view of the components of the body shield of FIG. 1.

FIG. 3 is a perspective view of a body shield embodying principles of the invention in another preferred form.

FIG. 4 is an exploded view of the components of the body shield of FIG. 3.

FIG. 5 is a perspective view of a body shield embodying principles of the invention in another preferred form.

FIG. 6 is an exploded view of the components of the body shield of FIG. 5.

FIG. 7 is a perspective view of a body shield embodying principles of the invention in yet another preferred form.

FIG. 8 is a cross-sectional view of the body shield of FIG. 7.

### DETAILED DESCRIPTION

With reference next to the drawing, there is shown a body shield 10 of the present invention in a preferred form. The body shield is designed to protect a user from harmful heat as well as low frequency to higher frequency electromagnetic fields and radiations, including radio frequency (RF) radiation, produced from portable electronic devices ED.

The body shield 10 includes a multi-layered core 11 which is encased within an outer casing 12. The multi-layered core 11 includes a first layer 14, a second layer 15, and a third layer 16. The core layers may be bonded together or be positioned one on top of the other and maintained in place by the outer casing. The outer casing 12 includes a top layer 18 and a bottom layer 19 sealed around its periphery to the top layer 18.

The first layer 14 is preferably made of a magnetic metal alloy comprised of at least 80 percent nickel and iron. Alternatively, the first layer may be made of a composite material constructed with a polymer film or non-woven carbon fiber cloth with a variety of surface penetrating or infused metallic and non-metallic compounds, such as the RF shielding fabric-like coated non-woven material made by Conductive Composites Company of Heber City, Utah as model number 2-1.208 and 2-0.04-208. Preferably, the material of the core first layer 14 is a mu-metal and is for shielding a user from extremely low frequency (ELF) electromagnetic radiation, i.e., it eliminates electromagnetic radiation in the range of 0 to 300 Hz. As such, it may be referred to as a magnetic field and radiation shielding having a very high permeability and very low coercive force, which supports the formation of a magnetic field within itself. This type of mu-metal material layer is sold by Carpenter Technology Corporation of Wyomissing, Pa., as part number 999-912 and referred to as Carpenter HyMu 80 Alloy. The first layer 14 has a preferred thickness of between 0.003 and 0.020 inches.

The core second layer 15 is preferably made of a carbon cloth or carbon fiber lamination medium and is for shielding a user from radio frequency (RF) or higher frequency electromagnetic radiation (EMR), i.e., it absorbs higher frequency electromagnetic radiation which is in the range of 800 MHZ to 10 GHz with minimal reflection. As such, it may be referred to as a EMF shielding and conductive or absorbing fabric. This layer of material is also sold by Less EMF, Inc. Of Albany, N.Y. under the name Microwave Absorbing Sheet. The second layer 15 has a preferred thickness of between 0.015 and 0.125 inches. The carbon cloth may be comprised of random carbon fiber mesh, but may also be a weave, lamination, sheet or the like.

The core third layer 16 is preferably a non-magnetic, aluminum foil layer and is for shielding a user from radio frequency electromagnetic radiation. The third layer 16 is intended to conduct the radio frequency electromagnetic radiation (higher frequency electromagnetic radiation) in a direction back towards the second layer so that it may once again have the opportunity to be absorbed by the carbon cloth second layer. The third layer 16 has a preferred thickness of between 0.004 and 0.125 inches. As an alternative, other non-magnetic metal foil layers may be utilized such as copper, silver, etc.

The outer casing top layer 18 is preferably a plastic, generally thermal resistive, thermal resistant, heat resistant, or near non-thermal conducting material, these terms being interchangeably used herein, such as a polypropylene and is for shielding a user from heat produced by the electronic device positioned upon the top layer 18. The thermal non-conductive nature of the plastic is such that it reduces or eliminates the transfer of heat produced by the electronic device ED into the core and to the user. The top layer 18 has a preferred thickness of between 0.030 and 0.150 inches.

The outer casing bottom layer 19 is also preferably a plastic, generally non-thermal conducting material, such as polypropylene and is for further shielding a user from heat produced by the electronic device. Again, the thermal non-conductive nature of the plastic is such that it reduces or eliminates the transfer of heat produced by the electronic device ED from reaching the user. The bottom layer 18 has a preferred thickness of between 0.030 and 0.150 inches.

The bottom layer 19 may be joined to the top layer 18 through mechanical means (snap type fitment), adhesives, welds, or any other conventionally known manner of joining two layers. It is preferred that the top layer be softer than the bottom layer to reduce slippage of an electronic device positioned upon the body shield 10. Also, it is preferred that the bottom layer be stiffer that the top lay to provide a somewhat rigid support structure to the body shield.

In use, the body shield may be place on the user's lap or upon another structure such as a table and an electronic device is place upon the body shield top surface of the top layer 18. The heat and electromagnetic radiation emitted from the electronic device is either absorbed or resisted by the body shield so that it does not reach the user's body positioned below the body shield. The soft top layer helps to prevent the electronic device from slipping should the body shield be tilted or moved. Furthermore, the rigidity of the body shield aids in supporting the electronic device upon an uneven surface such as one's lap.

The present invention was tested for extremely low frequency electromagnetic radiation and radio frequency electromagnetic radiation shielding effectiveness. The test was conducted in a Lindgren modular shielded room measuring 24 feet by 10 feet by 10.5 feet and was lined with FT-100 ferrite panels, FAA-400 and EHP-18PCL Pyramid Absorbers. The chamber was verified to comply with the −0, +6 dB field uniformity requirement of IEC 61000-4-3. The shielding effectiveness is determined by commonly known standards. Since spectrum analyzers read power, shielding effectiveness is determined by the dB difference between the two shielded and unshielded power levels, read in dBm. The testing found that the extremely low frequency electromagnetic radiation shielding effectiveness at 300 Hz was approximately 98.25% while at 60 Hz is was approximately 95.16%. The testing also found that the radio frequency electromagnetic radiation shielding effectiveness was as follows: at a frequency of 800 MHZ the shielding effectiveness was −36.1 dB (horizontal) and −30.0 dB (vertical) resulting in a shielding effectiveness in percent as 99.97545% and 99.91872%, respectively; at a frequency of 1700 MHZ the shielding effectiveness was −34.9 dB (horizontal) and −26.1 dB (vertical) resulting in a shielding effectiveness in percent as 99.96764% and 99.75453%, respectively; at a frequency of 1900 MHZ the shielding effectiveness was −34.2 dB (horizontal) and −25.8 dB (vertical) resulting in a shielding effectiveness in percent as 99.961198% and 99.73697%, respectively; at a frequency of 2100 MHZ the shielding effectiveness was −33 dB (horizontal) and −24.5 dB (vertical) resulting in a shielding effectiveness in percent as 99.94988% and 99.64519%, respectively; and at a frequency of 5000 MHZ the shielding effectiveness was −28.9 dB (horizontal) and −21.1 dB (vertical) resulting in a shielding effectiveness in percent as 99.87118% and 99.22375%, respectively. This test data shows an extremely effective shielding of both low frequency and radio frequency electromagnet radiation.

It should be understood that the body shield may be of any size and shape. Typically, the body shield is configured to a given application, for example, if one desires a shield to protect themself from the thermal or electromagnetic radiation from a laptop computer the shield is configured to completely underlay such. By way of another example, if one desires to protect themself from the thermal or electromagnetic radiation from a cell phone the body shield would be made smaller to accommodate or better fit this particular use.

It should be understood that the body shield is lightweight and portable. Furthermore, the body shield provides a complete protection across a wide spectrum of the electromagnetic radiation field, including thermal radiation, extremely low frequency emissions (0 to 300 Hz), and higher frequency radiations (radio frequency (RF) electromagnetic radiation) in the range of 800 Hz to 10 GHz. The device may also be used to protect electronic devices from other electronic devices.

It should be understood that additional or multiple layers of the same or additional materials may be added to the body shield to provide additional protection. For example, a second non-magnetic aluminum foil layer may be positioned between the core first layer and the core second layer to provide additional higher frequency electromagnetic radiation conductive capabilities prior to such reaching the second layer.

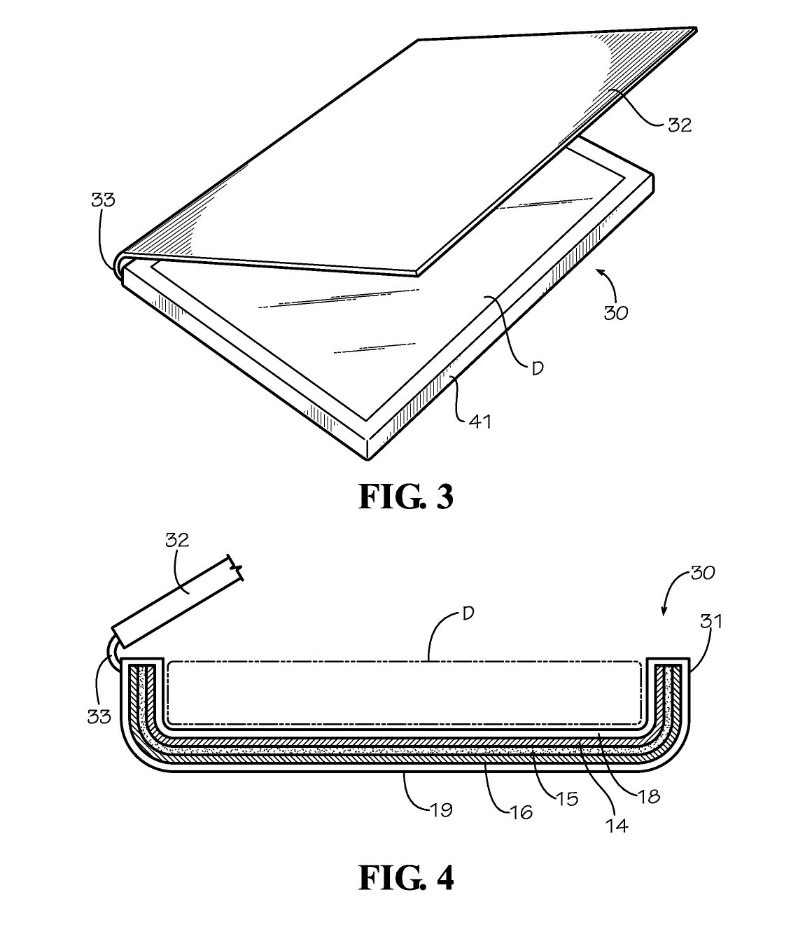

With reference next to FIGS. 3 and 4, there is shown a body shield 30 in another preferred form. Here the body shield 30 is conformed to fit snugly about a device D, such as a tablet computer, cellular telephone or the like, similar to a protective case for such. As such, the body portion includes a floor 34 and sidewalls 35 which together closely surround the periphery of the device so as the contain the device therein.

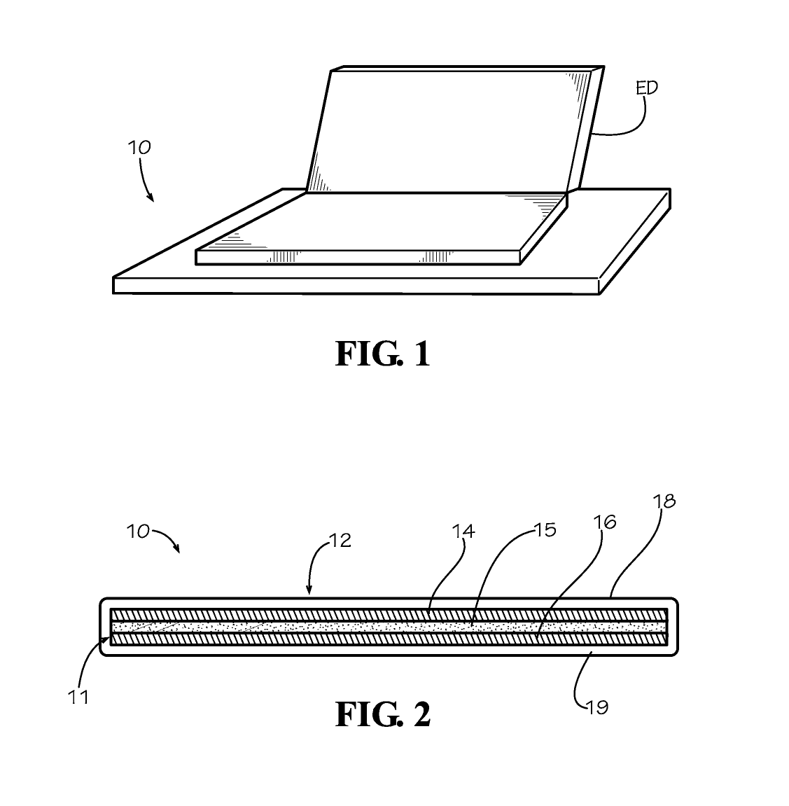

The body shield 30 includes a body portion 31, configured to be mounted to the device D, and a cover 32 configured to overlay a screen of the device. The cover 32 is pivotally coupled to the body portion 31 along a hinge 33. The body portion 31 is similar to that already disclosed in reference to the embodiment of FIGS. 1 and 2. The body portion 31 includes a core 11 which includes a first layer 14 positioned farthest from the device D, a second layer 15, and a third layer 16. The body portion also has an outer casing 12 which includes a top layer 18 and a bottom layer 19 sealed around its periphery to the top layer 18.

Again, the core first layer is preferably a mu-metal and is for shielding a user from extremely low frequency (ELF) electromagnetic radiation. The core second layer is preferably made of a carbon medium and is for shielding a user from radio frequency (RF) or high frequency electromagnetic radiation (EMR). The core third layer 16 is preferably a non-magnetic layer, such as aluminum foil, and is for shielding a user from radio frequency electromagnetic radiation.

The outer casing may be made of the previously described materials or of a thinner more flexible material, such as cloth, vinyl, leather or other material, as the rigid support in not mandatory in use with tablets, cellular telephones, and the like.

In use, the body portion 31 is fitted over and about the device so that it conforms to and firmly holds the device. The cover may then be positioned over the screen or display of the device to protect it from harm when not in use. The cover may be pivoted to remove it from an overlaying position when a user wishes to view the display of the device.

The electromagnetic radiation emitted from the device is either absorbed or conducted by the body shield so that it does not reach the user's body, as previously described in detail.

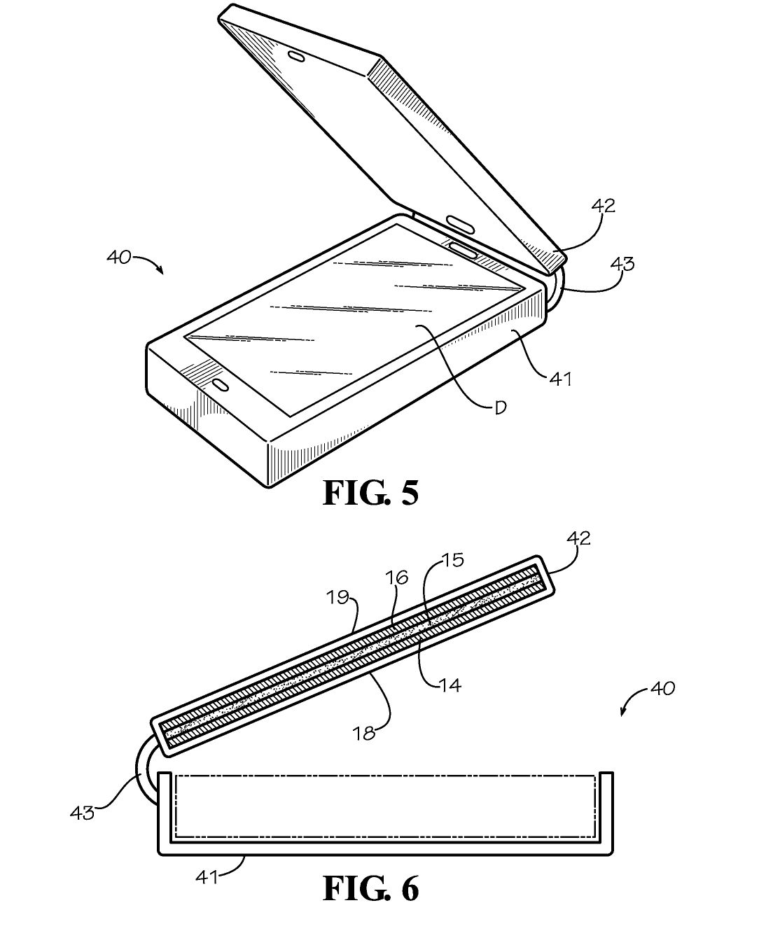

With reference next to FIGS. 5 and 6, there is shown a body shield 40 in another preferred form. Here the body shield 40 is conformed to fit snugly about a device D, such as cellular telephone or the like, similar to a protective case for such. As such, the body portion includes a floor 44 and sidewalls 45 which together closely surround the periphery of the device so as the contain the device therein. It should be noted that the sidewalls 45 may or may not include the core materials.

The body shield 40 includes a body portion 41, configured to be mounted to the device D, and a cover 42 configured to overlay a screen of the device. The cover 42 is pivotally coupled to the body portion 41 along a hinge 43. The main difference in this embodiment is that the shielding materials are contained within the cover 42 rather than within the body portion 41. As such, the cover 42 is similar to that already disclosed in reference to the embodiment of FIGS. 1 and 2. The cover 42 includes a core 11 which includes a first layer 16 positioned farthest from the device D, a second layer 15, and a third layer 14. The cover also has an outer casing 12 which includes a top layer 19 and a bottom layer 18 sealed around its periphery to the top layer 19. The cover includes appropriately positioned holes over the speaker or earphone of the phone, as need be, to allow the unimpeded passage of sound.

Again, the core first layer is preferably a mu-metal and is for shielding a user from extremely low frequency (ELF) electromagnetic radiation. The core second layer is preferably made of a carbon medium and is for shielding a user from radio frequency (RF) or high frequency electromagnetic radiation (EMR). The core third layer 14 is preferably a non-magnetic layer, such as aluminum foil, and is for shielding a user from radio frequency electromagnetic radiation.

The outer casing may be made of the previously described materials or of a thinner more flexible material, such as cloth, vinyl, leather or other material, as the rigid support in not mandatory in use with tablets, cellular telephones, and the like.

In use, the body portion 41 is fitted over and about the device so that it conforms to and firmly holds the device. The cover may then be positioned over the screen or display of the device to protect it from harm. Additionally, the cover shields the user from electromagnetic radiation as it is positioned between the device and the user during use as well as it being carried by the user, such as within a pocket, purse, jacket, or the like. The cover may be pivoted to remove it from an overlaying position when a user wishes to view the display of the device.

The electromagnetic radiation emitted from the device is either absorbed or resisted by the body shield so that it does not reach the user's body, as previously described in detail.

It should be understood that the body shield may also include a body portion including a core, such as that shown in the embodiment of FIGS. 3 and 4, and a cover also including a core, such as that shown in the embodiments of FIGS. 5 and 6. Also, the body shield may include less than all the layers shown in the preferred embodiment, however, this is does not provide the maximum shielding capabilities.

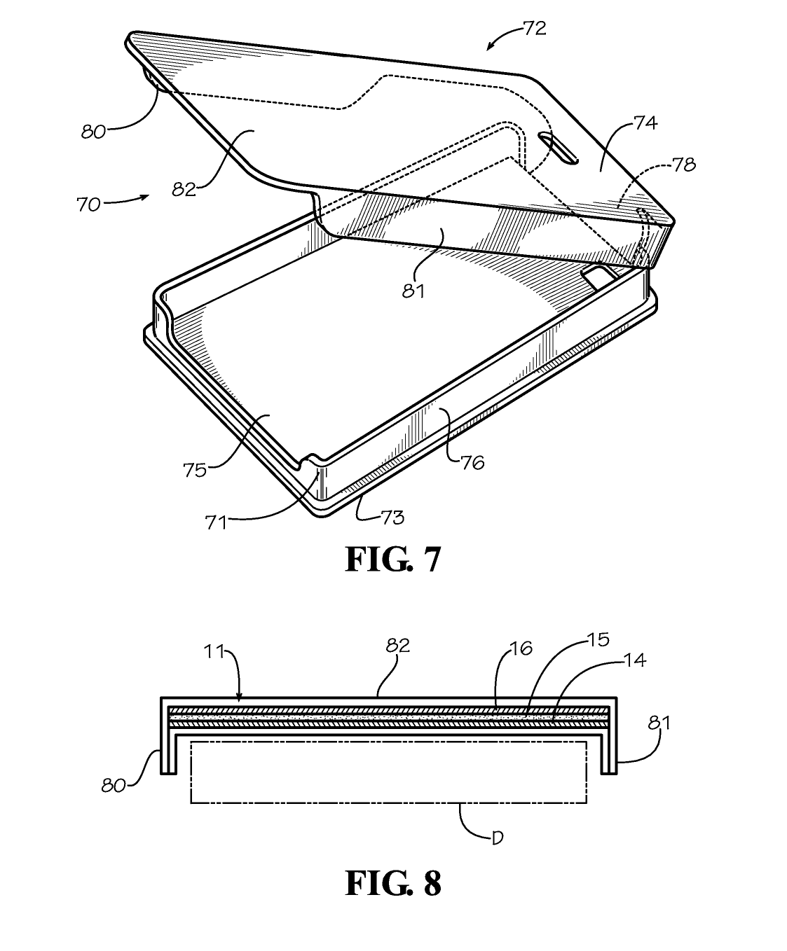

With reference next to FIGS. 7 and 8, there is shown a body shield 70 in another preferred form. Here the body shield 70 is conformed to fit snugly about a device D, such as cellular telephone or the like, similar to a protective case for such. The body shield 70 includes a resilient body portion or cradle 71 and an outer covering 72 having a bottom portion 73 and a cover or top portion 74. As such, the cradle 71 includes a floor 75 and sidewalls 76 which together closely surround the periphery of the device so as the contain the device therein.

The outer covering top portion 74 includes a left or first sidewall or wing 80 and a right or second sidewall or wing 81, each of which extend generally perpendicular to a central portion 82. The left and right wings 80 and 81 are intended to cover or overlay a majority of the side area of a device. The left and right wings are configured to fit snugly against the body portion 71 to aid in keeping the top portion 74 in a closed position against the top of the device D, i.e., they help in keeping the outer covering in a closed configuration through frictional contact between the wings and the body portion.

The cover or top portion 74 is pivotally coupled to the bottom portion 73 along a hinge 78. The shielding materials are contained within the central portion 82 of the top portion 74. The core 11 includes a first layer 16 positioned farthest from the device D, a second layer 15, and a third layer 14. The outer covering 72 also has an outer casing 12 which includes an external facing first layer 19 and an internal facing second layer 18 sealed around its periphery to the first layer 19. The cover 74 may include appropriately positioned holes over the speaker or earphone of the phone, as need be, to allow the unimpeded passage of sound. The core material extends past the peripheral edges or sides of the device, preferably past all peripheral sides, by at least 0.020 inches. The extension of the core material past the sides of the device ensures that the electromagnetic radiation from the device does not radiate or extend around the periphery or side edges of the core.

Again, the core first layer 16 is preferably a mu-metal and is for shielding a user from extremely low frequency (ELF) electromagnetic radiation. The core second layer 15 is preferably made of a carbon medium and is for shielding a user from radio frequency (RF) or high frequency electromagnetic radiation (EMR). The core third layer 14 is preferably a non-magnetic layer, such as aluminum foil, and is for shielding a user from radio frequency electromagnetic radiation.

The outer covering 72 may be made of the previously described materials or of a thinner more flexible material, such as cloth, vinyl, leather or other material, as the rigid support in not mandatory in use with tablets, cellular telephones, and the like.

In use, the body portion 71 is fitted over and about the device so that it conforms to and firmly holds the device. The outer covering top portion 74 may then be positioned over the screen or display of the device to protect it from harm. Additionally, the outer covering 72 shields the user from electromagnetic radiation as it is positioned between the device and the user during use as well as it being carried by the user, such as within a pocket, purse, jacket, or the like. The outer covering top portion 74 may be pivoted to remove it from an overlaying position when a user wishes to view the display of the device.

The electromagnetic radiation emitted from the device is either absorbed or resisted by the body shield so that it does not reach the user's body, as previously described in detail.

It should be understood that the body shield may include less than all the layers shown in the preferred embodiment, however, this is does not provide the maximum shielding capabilities. Depending on the amount of protection wanted by the shield, the core material may also be included in the bottom portion 73 and sidewalls 80 and 81. However, this may also limit the communication capabilities of the device due to the restriction of signals to and from the device.

It should also be understood that the sidewalls or wings may be configured to extend from the bottom portion 73 rather that the top portion 74.

It thus is seen that a body shield is now provided that overcomes problems long associated with those of the prior art. Though the body shield has herein been shown in a preferred form, it may, or course, be used in other applications or in other configurations. It should be understood that many modifications, additions and deletions may be made to the preferred embodiment that has been illustrated and described without departure from the spirit and scope of the invention as set forth in the following claims.

1. A body shield for shielding a person from thermal and electromagnetic radiation from a portable electronic device, the body shield comprising,
an outer covering having a core and an outer casing encasing said core, said outer covering including a central portion configured to removably overlay a top surface of the portable electronic device and at least one sidewall extending from said central portion configured to overlay a side surface of the portable electronic device, said core including a first layer having a material composition for shielding extremely low frequency electromagnetic radiation, a second layer having a material composition for absorbing higher frequency electromagnetic radiation.

2. The body shield of claim 1 wherein said outer covering at least one sidewall includes two sidewalls extending from opposite side edges of said central portion.

3. The body shield of claim 1 wherein said core extends past the periphery of the portable electronic device.

4. The body shield of claim 1 wherein said outer covering also includes a bottom portion configured to overlay a bottom surface of the portable electronic device.

5. The body shield of claim 1 wherein said core further includes a third layer having a material composition for conducting higher frequency electromagnetic radiation.

6. The body shield of claim 1 wherein said core first layer is a magnetic metal alloy.

7. The body shield of claim 1 wherein said core second layer is a carbon based material.

8. The body shield of claim 5 wherein said core third layer is a non-magnetic metal foil.

9. The body shield of claim 8 wherein said core third layer non-magnetic metal foil is an aluminum foil.

10. A body shield for shielding a person from thermal and electromagnetic radiation from a portable electronic device, the body shield comprising,
an outer covering having a core and an outer casing encasing said core, said outer covering including a central portion configured to removably overlay a top surface of the portable electronic device and at least one sidewall extending from said central portion configured to overlay a side surface of the portable electronic device, said core including a first layer having a material composition for shielding extremely low frequency electromagnetic radiation, a second layer having a material composition for conducting higher frequency electromagnetic radiation.

11. The body shield of claim 10 wherein said outer covering at least one sidewall includes two sidewalls extending from opposite side edges of said central portion.

12. The body shield of claim 10 wherein said core extends past the periphery of the portable electronic device.

13. The body shield of claim 10 further comprising a bottom portion configured to overlay a bottom of the portable electronic device.

14. The body shield of claim 10 wherein said core further includes a third layer having a material composition for absorbing higher frequency electromagnetic radiation.

15. The body shield of claim 10 wherein said core first layer is a magnetic metal alloy.

16. The body shield of claim 11 wherein said core third layer is a carbon based material.

17. The body shield of claim 10 wherein said core second layer is a non-magnetic metal foil.

18. The body shield of claim 15 wherein said core second layer non-magnetic metal foil is an aluminum foil.

19. A body shield for shielding a person from thermal and electromagnetic radiation from a portable electronic device, the body shield comprising,
a body portion configured to fit about and hold the portable electronic device, and
an outer covering pivotally coupled to said body portion, said outer covering having a first portion and a second portion pivotally coupled to said first portion, one said portion of said first and second portion including a central portion and a first sidewall extending from the central portion, said central portion having a core and an outer casing overlaying said core, said core including a first layer having a material composition for shielding extremely low frequency electromagnetic radiation, a second layer having a material composition for absorbing higher frequency electromagnetic radiation.

20. The body shield of claim 19 wherein said one said portion of said first and second portion further comprises a second sidewall extending from said central portion opposite said first sidewall.

21. The body shield of claim 19 wherein said core extends past the periphery of the portable electronic device.

22. The body shield of claim 20 wherein both said first and second portions and said sidewall associated with one said portion include a first layer having a material composition for shielding extremely low frequency electromagnetic radiation, a second layer having a material composition for absorbing higher frequency electromagnetic radiation.

23. The body shield of claim 19 wherein said core further includes a third layer having a material composition for conducting higher frequency electromagnetic radiation.

24. A body shield for shielding a person from thermal and electromagnetic radiation from a portable electronic device, the body shield comprising,
a body portion configured to fit about and hold the portable electronic device, and
an outer covering pivotally coupled to said body portion, said outer covering having a first portion and a second portion pivotally coupled to said first portion, one said portion of said first and second portion including a central portion and a first sidewall extending from the central portion, said central portion having a core and an outer casing overlaying said core, said core including a first layer having a material composition for shielding extremely low frequency electromagnetic radiation, a second layer having a material composition for conducting higher frequency electromagnetic radiation.

25. The body shield of claim 24 wherein said core extends past the periphery of the portable electronic device.
